(19) United States
(12) Patent Application Publication
(10) Pub. No.: US 2017/0101307 A1
(43) Pub. Date: Apr. 13, 2017

(54) SEMICONDUCTOR PACKAGE

(71) Applicant: SAMSUNG ELECTRO-MECHANICS CO., LTD., Suwon-si (KR)

(72) Inventors: Chang Hyun LIM, Suwon-si (KR); Tae Hun LEE, Suwon-si (KR); Dae Hun JEONG, Suwon-si (KR)

(73) Assignee: SAMSUNG ELECTRO-MECHANICS CO., LTD., Suwon-si (KR)

(21) Appl. No.: 15/181,480

(22) Filed: Jun. 14, 2016

(30) Foreign Application Priority Data
Oct. 8, 2015 (KR) 10-2015-0141825

(51) Int. Cl. B81B 7/00; G01D 11/24; H01L 23/053; H01L 25/16; H01L 23/00

(52) U.S. Cl. CPC B81B 7/008; H01L 25/16; H01L 24/32; H01L 24/17; H01L 24/48; H01L 24/73; H01L 23/053; G01D 11/245; B81B 2201/0235; B81B 2201/0264; B81B 2207/012; H01L 2224/32225; H01L 2924/1461; H01L 2924/15153; H01L 2224/16225; H01L 2224/16055; H01L 2224/16057; H01L 2224/73265; H01L 2224/2919; H01L 2224/48091; H01L 2224/48106; H01L 2224/48225

(57) ABSTRACT

There is provided a semiconductor package that comprises a board; a semiconductor chip disposed on the board and having an installation recess; an adhesive layer disposed within the installation recess; and a sensor unit disposed on the adhesive layer.

### CROSS-REFERENCE TO RELATED APPLICATION

This application claims the benefit under 35 USC 119(a) of Korean Patent Application No. 10-2015-0141825 filed on Oct. 8, 2015 in the Korean Intellectual Property Office, the disclosure of which is incorporated herein by reference for all purposes.

### BACKGROUND

1. Field

The following description relates to a semiconductor package.

2. Description of Related Art

Recently, there has been a need for development of sensors having a higher degree of accuracy than that of existing sensors for new applications. In addition, in order to accurately measure changes to a sensor's state, it is necessary to minimize the influence of undesired stress.

To this end, various attempts have been made through changes in the structure of semiconductor packages and devices.

Also, for mobile applications like wearable devices, it is desirable to realize a sensor module that has a relatively thin profile. However, when a sensor module is manufactured by stacking a board, a semiconductor chip, and a sensor, it is difficult to adjust the overall thickness of a mobile device that includes the sensor module due to the thickness of an adhesive layer.

Thus, it is necessary to develop a semiconductor package structure capable of withstanding external impact or force by increasing the thickness of the adhesive layer without increasing the overall profile or thickness of the semiconductor package.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor package comprises a board, a semiconductor chip, an adhesive layer, and a sensor unit. The semiconductor chip disposed on the board and has an installation recess. The adhesive layer disposed within the installation recess. The sensor unit disposed on the adhesive layer.

In the semiconductor package, the thickness of the adhesive layer may substantially correspond to a depth of the installation recess.

A solder ball may be disposed between the semiconductor chip and the board. The solder ball is used to connect the semiconductor chip to the board.

The installation recess may have a quadrangular shape. The installation recess may have a shape that substantially conforms to a surface of the sensor unit disposed on the adhesive layer.

The sensor unit may include a sensor die stacked on the adhesive layer and a pressure sensor installed in the sensor die.

The pressure sensor and the board may be electrically connected through wire bonding.

The sensor unit may be configured as an accelerometer.

A solder ball, by which the board is to be mounted on the main board, may be installed on a lower surface of the board.

The semiconductor package may further comprise a cap member forming an airtight enclosure with the board. The airtight enclosure is disposed over the sensor unit and the semiconductor chip.

The cap member is formed of metal or plastic. The adhesive layer may be formed of a polymer material.

In another general aspect, a semiconductor package comprises a main board, a board, a solder ball, a semiconductor chip, an adhesive layer, a sensor unit, and a cap member. The board is disposed on the main board. The solder ball is disposed between the board and the main board. The solder ball connects the board to the main board. The semiconductor chip is disposed on the board and has an installation recess formed on an upper surface thereof. An adhesive layer is disposed within the installation recess. The sensor unit is disposed on the adhesive layer. The cap member forms an airtight enclosure with the board. The airtight enclosure is disposed over the sensor unit and the semiconductor chip.

A thickness of the adhesive layer may substantially correspond to a depth of the installation recess. The installation recess may have a quadrangular shape.

The sensor unit and the board may be electrically connected through wire bonding.

In another general aspect, a semiconductor package comprises a board, a semiconductor chip, and a sensor unit. The semiconductor chip has a first surface and a second surface. The second surface of the semiconductor chip is disposed on the board. The first surface of the semiconductor chip has first and second surface portions. The first surface portion including an installation recess. An adhesive layer is disposed within the installation recess. The sensor unit is disposed on the adhesive layer.

The installation recess may substantially conform to the shape of a surface of the sensor unit contacting the adhesive layer.

The first surface portion and the second surface portion may have different contours.

The semiconductor chip may be reversedly disposed on the board.

Other features and aspects will be apparent from the following detailed description, the drawings, and the claims.

### BRIEF DESCRIPTION OF DRAWINGS

FIG. 1 is a cross-sectional view of an example schematically illustrating a semiconductor package.

FIG. 2 is a plan view illustrating an example of a semiconductor chip in the semiconductor package of FIG. 1.

FIG. 3 is a view illustrating another example of a configuration of a semiconductor package.

FIG. 4 is a plan view illustrating an example of a semiconductor chip provided in the semiconductor package of FIG. 3.

FIG. 5 is a view illustrating another example of a configuration of a semiconductor package.

FIG. 6 is a view illustrating another example of a configuration of a semiconductor package.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present disclosure. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

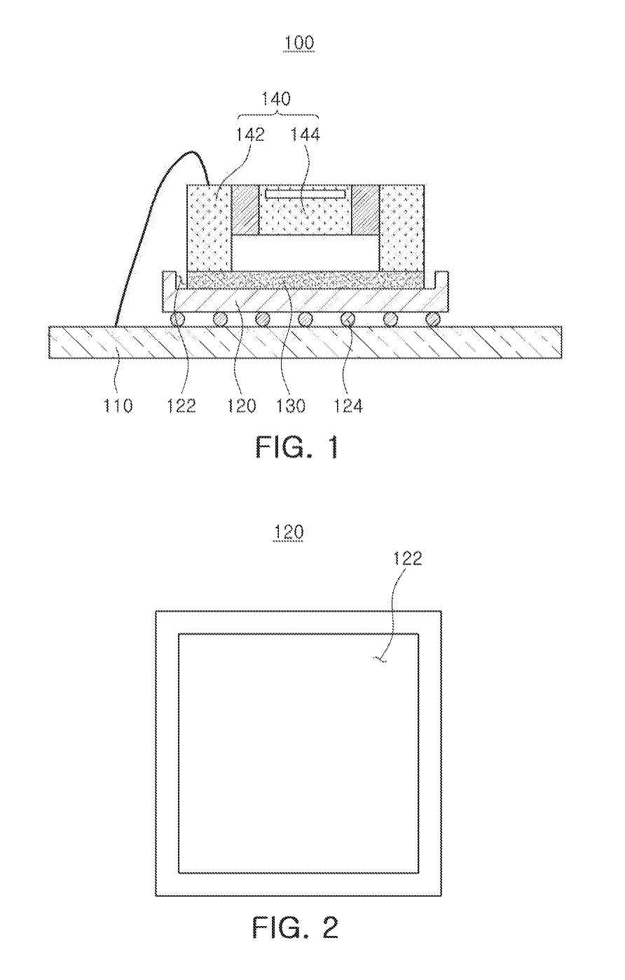

FIG. 1 is a cross-sectional view of an example schematically illustrating a semiconductor package, while FIG. 2 is a plan view illustrating an example of a semiconductor chip in the semiconductor package of FIG. 1.

Referring to FIGS. 1 and 2, a semiconductor package 100 includes a board 110, a semiconductor chip 120, an adhesive layer 130, and a sensor unit 140. The semiconductor chip 120 may be an application specific integrated circuit (ASIC) chip.

The board 110 may have a plate shape and may have a patterned layer (not shown). An electrode layer (not shown) allowing the semiconductor chip 120 to be mounted thereon may be provided on an upper surface of the board 110. That is, the semiconductor chip 120 may be mounted on the board 110.

The semiconductor chip 120 is mounted on the board 110. An installation recess 122 is formed on the semiconductor chip 120 through an etching process or another similar process used during microfabrication. The installation recess 122 is formed on the underside of the semiconductor chip 120.

When the semiconductor chip 120, of which the underside surface thereof has been etched, is reversedly mounted on the board 110 and a sensor unit 140 is disposed thereon, a thickness corresponding to the etching depth is gained in reducing the overall profile of the semiconductor package 100.

When viewed top-down, the installation recess 122 provided on the semiconductor chip 120 may have a quadrangular shape as illustrated in FIG. 2. However, the present disclosure is not limited thereto and the shape of the installation recess 122 may be variously modified according to a shape of the sensor unit 140 disposed on the semiconductor chip 120. That is, the installation recess 122 may have a shape corresponding to the shape of the sensor unit 130 including triangular, circular, and hexagonal shapes when viewed top-down, for example.

The depth of the installation recess 122 may correspond to a thickness of the adhesive layer 130.

Solder balls 124, on which the semiconductor chip 120 is to be mounted on the board 110, are provided between the semiconductor chip 120 and the board 110. The solder balls 124 may be disposed to be spaced apart from one another on the lower surface of the reversedly mounted semiconductor chip 120, and may be adhered to an electrode layer (not shown) formed on an upper surface of the board 110. The sensor unit 140 is then stacked on the adhesive layer 130.

Since the difference in coefficients of thermal expansion between the semiconductor chip 120, formed of silicon (Si) as a main ingredient, and the solder balls 124 is relatively small, adhesion defects due to the difference in coefficient of thermal expansion therebetween is reduced.

The adhesive layer 130 is disposed within the installation recess 122 and may be configured as a bonding layer formed of a polymer such as a die attach film (DAF).

Also, as described above, the adhesive layer 130 may have a thickness corresponding to the depth of the installation recess 122 and is formed of a soft and/or elastic material.

Thus, since the adhesive layer 130 is formed of a soft and/or elastic material, it provides shock and impact protection by absorbing external force and shock applied thereto. In the semiconductor package 100, when external force or shock is attendant on the sensor unit 140 disposed on the adhesive layer 130, transmission of the impact to the sensor unit 140 is limited or eliminated.

In addition, since the adhesive layer 130 is disposed within the installation recess 122, an increase in the thickness or overall profile of the semiconductor package 100 due to the adhesive layer 130 is prevented.

The sensor unit 140 includes a sensor die 142 stacked on the adhesive layer 130 and a pressure sensor 144 installed in the sensor die 142.

The pressure sensor 144 and the board 110 may be electrically connected through bonding-wire.

In the present example, the pressure sensor 144 is provided in the sensor unit 140 but the present disclosure is not limited thereto and other types of sensors may be included in the sensor unit 140.

As mentioned above, since the adhesive layer 130 has a thickness corresponding to the depth of the installation recess 122 and is formed of a soft and/or elastic material that provides shock and impact protection by absorbing external force. Thus, in a case in which external force is applied, transmission of the impact of the external force to the sensor unit 140 is reduced.

In addition, since the adhesive layer 130 is disposed within the installation recess 122, an increase in the thickness or profile of the semiconductor package 100 due to the adhesive layer 130 is negated.

Hereinafter, a semiconductor package according to another example will be described with reference to the accompanying drawings.

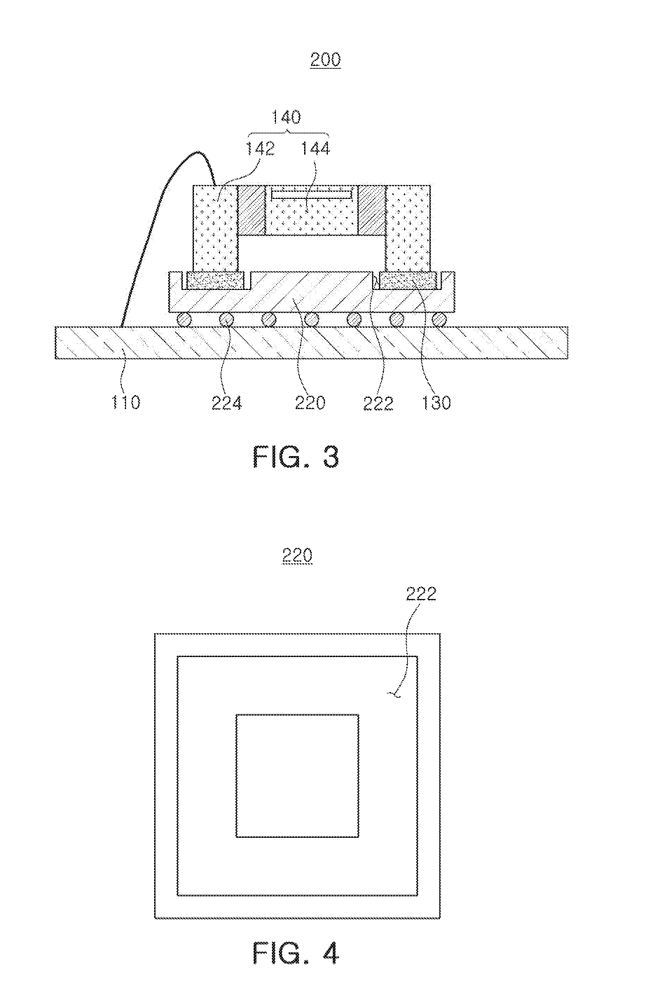

FIG. 3 is a view illustrating another example of a configuration of a semiconductor package, and FIG. 4 is a plan view illustrating an example of a semiconductor chip provided in the semiconductor package of FIG. 3.

Referring to FIGS. 3 and 4, a semiconductor package 200 includes a board 110, a semiconductor chip 220, an adhesive layer 130, and a sensor unit 140.

The board 110 may have a plate shape and may have a patterned layer (not shown). An electrode layer (not shown) allowing the semiconductor chip 220 to be mounted thereon may be provided on an upper surface of the board 110. That is, the semiconductor chip 220 may be mounted on the board 110.

The semiconductor chip 220 is mounted on the board 110. An installation recess 222 is formed on the semiconductor chip 120 through an etching process or another similar process used during microfabrication. The installation recess 222 is formed on the underside of the semiconductor chip 220.

The installation recess 222 of the semiconductor chip 220 may have a quadrangular ring shape when viewed top-down. Reducing the overall profile of the semiconductor chip 200 uniformly may result in output degradation. That is, in instances where the overall thickness or profile of the semiconductor chip 220 is reduced uniformly, characteristics of the semiconductor chip 220, such as measurement, or the like, may change due to temperature, leading to a possibility of degrading the output characteristics of the sensor unit 140. Thus, the installation recess 222 is only formed in a portion of the semiconductor chip 220 that adheres to the sensor unit 140.

A measurement portion of the semiconductor chip 220, which may be sensitive and thus easily affected in terms of thickness of the semiconductor chip 220, may be disposed in a thicker portion of the semiconductor chip 220. Whereas, a portion of the semiconductor chip 220, which may be less affected or may not affected in terms of thickness, may be disposed in a thinner portion in which the installation recess 222 is formed.

The shape of the installation recess 222 may be modified according to a shape of the sensor unit 140 and/or the resulting shape of the portion of the semiconductor chip not affected in terms of thickness. That is, the installation recess 222 may have a shape corresponding to a shape of the sensor unit 130 or may have a shape that is triangular, circular, and hexagonal ring when viewed top-down.

The depth of the installation recess 222 may correspond to a thickness of the adhesive layer 130.

Solder balls 224, by which the semiconductor chip 220 is to be mounted on the board 110, are provided on a lower surface of the semiconductor chip 120. The solder balls 224 may be disposed to be spaced apart from one another on the lower surface of the semiconductor chip 220, and may adhere to an electrode layer (not shown) provided on an upper surface of the board 110. The sensor unit 140 is then stacked on the adhesive layer 130.

Since the difference in coefficients of thermal expansion between the semiconductor chip 220, formed of silicon (Si) as a main ingredient, and the solder balls 224 is relatively small, adhesion defects due to differences in the coefficients of thermal expansion therebetween is reduced.

The adhesive layer 130 is disposed within the installation recess 222 and may be configured as a bonding layer formed of a polymer such as a DAF.

Also, as described above, the adhesive layer 130 may have a thickness corresponding to the depth of the installation recess 222 and may be formed of a soft and/or elastic material.

Thus, since the adhesive layer 130 is formed of a soft and/or elastic material, it provides shock and impact protection by absorbing external force and shock. Thus, in the semiconductor package 200, when external force or shock is attendant on the sensor unit 140 disposed on the adhesive layer, transmission of the impact to the sensor unit 140 is limited or reduced.

In addition, since the adhesive layer 130 is disposed within the installation recess 222, an increase in the thickness of the semiconductor package 200 due to the adhesive layer 130 is prevented.

The sensor unit 140 is mounted on the adhesive layer 130. The sensor unit 140 includes a sensor die 142 mounted on the adhesive layer 130 and a pressure sensor 144 installed in the sensor die 142.

The pressure sensor 144 and the board 110 may be electrically connected through bonding-wire.

In the present example, the pressure sensor 144 is provided in the sensor unit 140 but the present disclosure is not limited thereto and other types of sensors may be included in the sensor unit 140.

As mentioned above, since the adhesive layer 130 has a thickness corresponding to the depth of the installation recess 222 and is formed of a soft and/or material that provides shock and impact protection by absorbing external force. Thus, in a case in which external force is applied, transmission of the impact of the external force to the sensor unit 140 is reduced.

In addition, since the adhesive layer 130 is disposed within the installation recess 222, an increase in the thickness or profile of the semiconductor package 200 due to the adhesive layer 130 is negated.

Moreover, since the installation recess 222 is only formed in the portion of the sensor unit 140, a measurement portion of the semiconductor chip 220 that may be sensitive and thus easily affected in terms of thickness, may be disposed in a thicker portion of the semiconductor chip 220 that does not include the installation recess 222. A portion of the semiconductor chip 220 that is less sensitive to the thickness of the semiconductor chip 220 may be disposed in a thinner portion in which the installation recess 222 is formed.

By selectively determining the surface portion of the semiconductor chip 220 to etch the installation recess 222, the sensitivity of the semiconductor chip 220 to perform measurement functions is not affected.

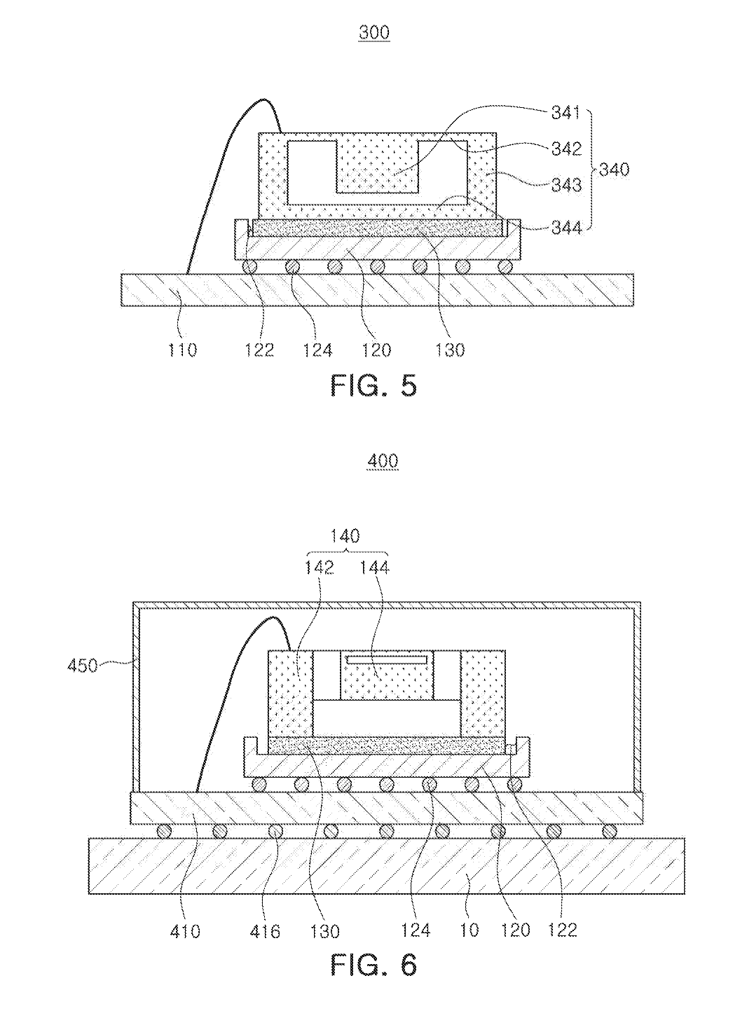

FIG. 5 is a view illustrating another example of a configuration of a semiconductor package.

Referring to FIG. 5, a semiconductor package 300 includes a board 110, a semiconductor chip 120, an adhesive layer 130, and a sensor unit 340.

The board 110 may have a plate shape and may have a patterned layer (not shown). An electrode layer (not shown) allowing the semiconductor chip 120 to be mounted thereon may be provided on an upper surface of the board 110. That is, the semiconductor chip 120 may be mounted on the board 110.

The semiconductor chip (or an application specific integrated circuit (ASIC)) 120 is mounted on the board 110. An installation recess 122 is formed in the semiconductor chip 120 through an etching or another similar process.

When the semiconductor chip 120, of which an underside surface thereof has been etched, is reversedly mounted on the board 110 and a sensor unit 340 is disposed thereon, a thickness corresponding to the etching depth is gained in reducing the overall profile of the semiconductor package 300.

When viewed top-down, the installation recess 122 provided on the semiconductor chip 120 may have a quadrangular shape as illustrated in FIG. 2. However, the present disclosure is not limited thereto and the shape of the installation recess 122 may be variously modified according to a shape of the sensor unit 340. That is, the installation recess 122 may have a shape corresponding to a shape of the sensor unit 340 or may have a shape that is triangular, circular, and hexagonal when viewed top-down.

The depth of the installation recess 122 may correspond to a thickness of the adhesive layer 130.

Solder balls 124, by which the semiconductor chip 120 is to be mounted on the board 110, are provided between the semiconductor chip 120 and the board 110. The solder balls 124 may be disposed to be spaced apart from one another on the lower surface of the reversedly mounted semiconductor chip 120, and may adhere to an electrode layer (not shown) formed on an upper surface of the board 110.

Since the difference in coefficients of thermal expansion between the semiconductor chip 120, formed of silicon (Si) as a main ingredient, and the solder balls 124 is relatively small, adhesion defects due to the differences in coefficients of thermal expansion therebetween is reduced.

The adhesive layer 130 is mounted within the installation recess 122 and may be configured as a bonding layer formed of a polymer such as a die attach film (DAF).

Also, as described above, the adhesive layer 130 may have a thickness corresponding to the depth of the installation recess 122 and is formed of a soft material.

Thus, since the adhesive layer 130 is formed of a soft and/or elastic material, it provides shock and impact protection by absorbing external force applied thereto. In the semiconductor package 300, when external force or shock is attendant on the sensor unit 340 disposed on the adhesive layer 130, transmission of the impact to the sensor unit 340 is limited or eliminated.

In addition, since the adhesive layer 130 is disposed within the installation recess 122, an increase in the thickness or overall profile of the semiconductor package 300 due to the adhesive layer 130 is prevented.

The sensor unit 340 includes a driving body 341, a flexible substrate unit 342, a support 343, and a lower cap 344.

In detail, the flexible substrate unit 342 includes a flexible substrate, a piezoelectric (PZT) material, and an electrode. The flexible substrate may be formed of a silicon substrate or a silicon-on-insulator (SOI) substrate, and a piezoelectric element and an electrode may be deposited on the flexible substrate to form a driving electrode (not shown) and a sensing electrode (not shown). The driving electrode serves to drive the driving body, and the sensing electrode serves to sense movement of the driving electrode to detect inertial force.

The driving body 341 is elastically-coupled to the flexible substrate unit 342 such that the driving body 341 changes position. When a voltage is applied to the driving electrode of the flexible substrate unit 342, the driving body 341 becomes movable.

The support 343 supports the driving body 341 and the flexible substrate unit 342, and the driving body 341 is supported by the support 113 such that the driving body 341 is freely movable in a floating state.

The driving body 341, the flexible substrate unit 342, and the support 343 may be integrally formed through an etching method.

The lower cap 344 serves to cover the driving body 341 and supportedly couples the sensor unit 340 to the semiconductor chip 120. The lower cap 344 may be formed of silicon, the same as a material of the driving body 341 and the support 343, or may be formed of Pyrex glass having a similar coefficient of thermal expansion. Silicon offers the advantages of being easier to work with and process.

The lower cap 344 is coupled to the support 343 by wafer level bonding and offers advantages of being easily processed and cost effect by maintaining the characteristics of piezoelectric thin film devices and bond at temperatures as low as 300° C. or lower. Polymer bonding using a photoresist or an epoxy is preferred to form a bonding part.

In this manner, the sensor unit 340 may have an inertial sensor, that is, an accelerometer; however, the present disclosure is not limited thereto and various sensors may be provided in the sensor unit 340.

As described above, since the adhesive layer 130 has a thickness corresponding to the depth of the installation recess 122 and is formed of a soft and/or material, in a case in which external force is applied thereto, the impact of the external force is absorbed by the adhesive layer 130; thus, reducing transmission of the impact to the sensor unit 340.

In addition, since the adhesive layer 130 is disposed within the installation recess 122, an increase in the thickness of the semiconductor package 300 due to the adhesive layer 130 is prevented.

FIG. 6 is a view illustrating another example of a configuration of a semiconductor package according.

Referring to FIG. 6, a semiconductor package 400 includes a board 410, a semiconductor chip 120, an adhesive layer 130, a sensor unit 140, and a cap member 450.

The board 410 may have a plate shape and may have a patterned layer (not shown). An electrode layer (not shown) allowing the semiconductor chip 120 to be mounted thereon may be provided on an upper surface of the board 410. That is, the semiconductor chip 120 may be mounted on the board 110.

Solder balls 416, by which the board 410 is to be installed on a main board 10, may be provided on a lower surface of the board 410.

The semiconductor chip (or an application specific integrated circuit (ASIC)) 120 is mounted on the board 410. An installation recess 122 is formed in the semiconductor chip 120 through an etching or another similar process.

When the semiconductor chip 120 in which an underside surface thereof has been etched and reversedly mounted on the board 410, a thickness corresponding to the etching depth is gained in reducing the overall profile of the semiconductor package 300.

When viewed top-down, the installation recess 122 provided in the semiconductor chip 120 may have a quadrangular shape as illustrated in FIG. 2. However, the present disclosure is not limited thereto and the shape of the installation recess 122 may be variously modified according to a shape of the sensor unit 140. That is, the installation recess 122 may have a shape corresponding to a shape of the sensor unit 130 or may have a shape that is triangular, circular, and hexagonal when viewed top-down.

The depth of the installation recess 122 may correspond to a thickness of the adhesive layer 130.

Solder balls 124, by which the semiconductor chip 120 is to be mounted on the board 410, are provided between the semiconductor chip 120 and the board 410. The solder balls 124 may be disposed to be spaced apart from one another on the lower surface of the semiconductor chip 120, and may adhere to an electrode layer (not shown) formed on an upper surface of the board 410.

In this manner, since a difference in coefficients of thermal expansion between the semiconductor chip 120 formed of silicon (Si) as a main ingredient and the solder balls 124 is small, an adhesion defect due to the differences in coefficients of thermal expansion therebetween is reduced.

The adhesive layer 130 is mounted within the installation recess 122. For example, the adhesive layer 130 may be configured as a bonding layer formed of a polymer, such as a die attach film (DAF).

Also, as described above, the adhesive layer 130 may have a thickness corresponding to the depth of the installation recess 122. The adhesive layer 130 may be formed of a soft material.

Thus, since the adhesive layer 130 is formed of a soft and/or elastic material, it provides shock and impact protection by absorbing external force applied thereto. In the semiconductor package 400, when external force or shock is attendant on the sensor unit 140 disposed on the adhesive layer 130, transmission of the impact to the sensor unit 140 is limited or eliminated.

In addition, since the adhesive layer 130 is disposed within the installation recess 122, an increase in a thickness of the semiconductor package 100 due to the adhesive layer 130 is prevented.

The sensor unit 140 may include a sensor die 142 mounted on the adhesive layer 130 and a pressure sensor 144 installed in the sensor die 142.

The pressure sensor 144 and the board 410 may be electrically connected through bonding-wire.

In the present example, a case in which the pressure sensor 144 is provided in the sensor unit 140 is described as an example, but the present disclosure is not limited thereto and types of sensors provided in the sensor unit 140 may be variously modified.

Also, the cap member 450 forms an airtight space together with the board 410. The cap member 450 may be formed of a metal or plastic and may have a box shape with a lower end portion thereof open.

Thus, since the sensor unit 140 is disposed in the airtight space formed by the cap member 450 and the board 410, damage to the sensor unit 140 due to external the impact of the external force may be prevented.

As described above, since the solder balls 416 are provided on the lower surface of the board 410, the semiconductor package 400 may be installed on the main board 10 through soldering.

Hereinbefore, the case in which the sensor unit includes the pressure sensor or the inertial sensor is described as an example, but the present disclosure is not limited thereto and may be applied to a package regarding a micro electro mechanical system (MEMS) sensor/actuator structure.

As set forth above, according to the different examples in the present disclosure, the impact or shock due to external force is reduced or eliminated without increasing an overall thickness or profile of the semiconductor package.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package comprising:
a board;
a semiconductor chip disposed on the board and having an installation recess;
an adhesive layer disposed within the installation recess; and
a sensor unit disposed on the adhesive layer.

2. The semiconductor package of claim 1, wherein a thickness of the adhesive layer substantially corresponds to a depth of the installation recess.

3. The semiconductor package of claim 1, wherein a solder ball is disposed between the semiconductor chip and the board, and the solder ball connects the semiconductor chip to the board.

4. The semiconductor package of claim 1, wherein the installation recess has a quadrangular shape.

5. The semiconductor package of claim 1, wherein the installation recess has a shape that conforms to a surface of the sensor unit disposed on the adhesive layer.

6. The semiconductor package of claim 1, wherein the sensor unit comprises a sensor die stacked on the adhesive layer and a pressure sensor installed in the sensor die.

7. The semiconductor package of claim 6, wherein the pressure sensor and the board are electrically connected through wire bonding.

8. The semiconductor package of claim 1, wherein the sensor unit comprises an accelerometer.

9. The semiconductor package of claim 1, wherein a solder ball, by which the board is to be mounted on the main board, is installed on a lower surface of the board.

10. The semiconductor package of claim 1, further comprising a cap member forming an airtight enclosure with the board, the airtight enclosure being disposed over the sensor unit and the semiconductor chip.

11. The semiconductor package of claim 10, wherein the cap member comprises metal or plastic.

12. The semiconductor package of claim 1, wherein the adhesive layer comprises a polymer material.

13. A semiconductor package comprising:
a main board;
a board disposed on the main board;
a solder ball disposed between the board and the main board, the solder ball connecting the board to the main board;
a semiconductor chip disposed on the board and having an installation recess formed on an upper surface thereof;
an adhesive layer disposed within the installation recess;
a sensor unit disposed on the adhesive layer; and
a cap member forming an airtight enclosure with the board, the airtight enclosure being disposed over the sensor unit and the semiconductor chip.

14. The semiconductor package of claim 13, wherein a thickness of the adhesive layer corresponds to a depth of the installation recess.

15. The semiconductor package of claim 13, wherein the installation recess has a quadrangular shape.

16. The semiconductor package of claim 13, wherein the sensor unit and the board are electrically connected through wire bonding.

17. A semiconductor package comprising:
a board;
a semiconductor chip having a first surface and a second surface, the second surface of the semiconductor chip being disposed on the board, the first surface of the semiconductor chip having first and second surface portions, the first surface portion including an installation recess;
an adhesive layer disposed within the installation recess; and
a sensor unit disposed on the adhesive layer.

18. The semiconductor package of claim 17, wherein the installation recess substantially conforms to the shape of a surface of the sensor unit contacting the adhesive layer.

19. The semiconductor package of claim 18, wherein the first surface portion and the second surface portion have different contours.

20. The semiconductor package of claim 17, wherein second surface of the semiconductor chip electrically connects to the sensor unit.
